(19) United States
(12) Patent Application Publication
(10) Pub. No.: US 2006/0234135 A1
(43) Pub. Date: Oct. 19, 2006

(54) Method for repairing mask-blank defects using repair-zone compensation

(75) Inventors: Stefan P. Hau-Riege, Fremont, CA (US); Donald W. Sweeney, San Ramon, CA (US); Anton Barty, Livermore, CA (US); Paul B. Mirkarimi, Sunol, CA (US); Daniel G. Stearns, Los Altos Hills, CA (US)

Correspondence Address: Alan H. Thompson;Deputy Laboratory Counsel, Lawrence Livermore National Laboratory, P.O. Box 808, L-703, Livermore, CA, 94551-0808, US

(73) Assignee: The Regents of the University of CA

(21) Appl. No.: 11/109,026

(22) Filed: Apr. 18, 2005

(51) Int. Cl. G03C 5/00; G21K 5/00; G03F 1/00

(52) U.S. Cl. 430/5; 430/322; 378/35

(57) ABSTRACT

A method for repairing mask-blank defects uses repair-zone compensation. Local disturbances are compensated over the post-defect-repair repair-zone by altering a portion of the absorber pattern on the surface of the mask blank. This enables the fabrication of defect-free (since repaired) X-ray Mo—Si multilayer mirrors. Repairing Mo—Si multilayer-film defects on mask blanks is a key for the commercial success of EUVL. It is known that particles are added to the Mo—Si multilayer film during the fabrication process. There is a large effort to reduce this contamination, but results are not sufficient, and defects continue to be a major mask yield limiter.

The United States Government has rights in this invention pursuant to Contract No. W-7405-ENG-48 between the United States Department of Energy and the University of California for the operation of Lawrence Livermore National Laboratory.

### BACKGROUND OF THE INVENTION

1. Field of the Invention

The present invention relates to minimizing defects in the components produced by an extreme ultraviolet lithography (EUVL) system, and more specifically, it relates to a method for repairing defects in a EUVL mask-blank

2. Description of Related Art

Extreme ultraviolet (EUV) lithography is the top contender for next generation lithography in high-volume semiconductor manufacturing for the 32 nm node and beyond. It utilizes 13.4 nm radiation as the exposure light source and employs Mo—Si multilayer stacks as the reflector for both optic mirrors and mask blanks.

EUV mask blanks are fabricated by depositing a reflective Mo/Si multilayer film onto super-polished substrates. The coated substrate is commonly referred to as a mask blank. Subsequently, a patterned absorber layer is disposed on the surface of the reflective multilayer coating.

Localized defects in the Mo/Si multilayer can significantly alter the reflected field and introduce errors in the lithographically printed image. A defect is roughly categorized herein as being either an amplitude defect or a phase defect FIG. 1A illustrates an amplitude defect 10 located toward the top of the multilayer 12. A phase defect 14 is located toward the bottom of the multilayer stack 16, as shown in FIG. 1B. Both amplitude and phase defects lead to a distortion of the reflected light, inducing a severe variation of the line width in the printed image, where the smallest features of critical dimensions (CD) are affected most. This variation in line width potentially renders an integrated circuit unusable.

Techniques for repairing localized defects have been suggested in (i) U.S. Pat. No. 6,821,682, titled “Repair Of Localized Defects In Multilayer-Coated Reticle Blanks For Extreme Ultraviolet Lithography,” incorporated herein by reference and (ii) U.S. patent application Ser. No. 09/896,722, titled “A Method To Repair Localized Amplitude Defects In A EUV Lithography Mask Blank,” incorporated herein by reference. The applicability of these techniques depends on the position of the defect in the multilayer stack. Phase defects, as shown in FIG. 2A, can be repaired by contracting the volume above the defect through local heating as shown in FIG. 2B. On the other hand, amplitude defects, such as amplitude defect 18 shown in FIG. 3A, can be repaired by removing the defect along with the surrounding multilayer altogether, as shown at 20 in FIG. 3B, and capping the top surface with a protective layer 22 to prevent oxidation, as shown in FIG. 3C.

Whereas both amplitude and phase defect repair techniques significantly reduce the defect-induced CD variation and allow the fabrication of functioning integrated circuits, a residual variation of the properties of the reflected light over the repair zone remains. This is acceptable for low-speed applications, but for high-speed integrated circuits such as microprocessors, CD variations limit the operating frequency. Critical signal paths determine the operating speed. Any CD variation potentially reduces the speed of signal propagation along critical paths and therefore needs to be avoided.

Therefore, a need exists for amplitude and phase defect repair techniques that significantly reduce the defect-induced CD variation and allow the fabrication of functioning integrated circuits, while compensating for any remaining unacceptable residual variation of the properties of the reflected light over the repair zone.

### SUMMARY OF THE INVENTION

It is an object of the present invention to provide a method for compensating for defect-repair-induced residual variation of optical properties across a mask blank repair zone.

It is another object to provide a method that alters a portion of an absorber pattern on a surface of a mask blank in proximity to the repair zone to compensate for a local disturbance of an electro-magnetic field induced by the repair zone.

Another object is to compensate for residual variation in an amplitude repair zone.

Still another object is to compensate for residual variation in a phase-defect-repair zone.

These and other objects will be apparent to those skilled in the art based on the disclosure herein.

As discussed above, both amplitude and phase defect repair techniques result in a residual variation of the properties of the reflected light over the repair zone. The present invention compensates for the defect-repair-induced residual variation of the optical properties across the repair zone through modification or alteration of a portion of the absorber pattern on the surface of the mask blank in proximity to the repair zone to compensate for the local disturbance of the electro-magnetic field induced by the repair zone.

The repair-zone compensation has to be handled differently for amplitude and phase defect repair techniques. Two alternative processes are herein provided for the amplitude-repair-zone compensation. The first process compensates for the overall drop of the reflectance over the repair zone. The second process accounts for the overall drop and the oscillations to produce a full compensation for the effect of the repair zone. Performing the repair on a grid simplifies the amplitude repair zone compensation. To compensate for the phase-defect-repair zone, the repair zone needs to be analyzed in detail and then one of several methods may be used to modify the absorber layer. One method corrects the absorber after the patterning has been completed. Another method corrects the absorber pattern layout prior to absorber patterning.

### BRIEF DESCRIPTION OF THE DRAWINGS

The accompanying drawings, which are incorporated into and form part of this disclosure, illustrate embodiments of the invention and together with the description, serve to explain the principles of the invention.

FIG. 1A shows an amplitude defect.

FIG. 1B shows a phase defect.

FIG. 2A shows a phase defect.

FIG. 2B shows a repaired phase defect.

FIG. 3A shows an amplitude defect.

FIG. 3B shows a removed amplitude defect.

FIG. 3C shows a repaired amplitude defect (protected by a cap layer).

FIG. 4A shows a lineout of the reflectance variation over the amplitude-defect repair zone.

FIG. 4B shows CD variation due to the reflectance drop.

FIG. 4C shows CD variation when the mask is compensated using a first process of the present invention.

FIG. 4D shows CD variation when the mask is compensated using a second process of the present invention.

FIG. 5 shows relative CD change of an isolated 35 nm-wide line as a function of the reflectance drop of the mask.

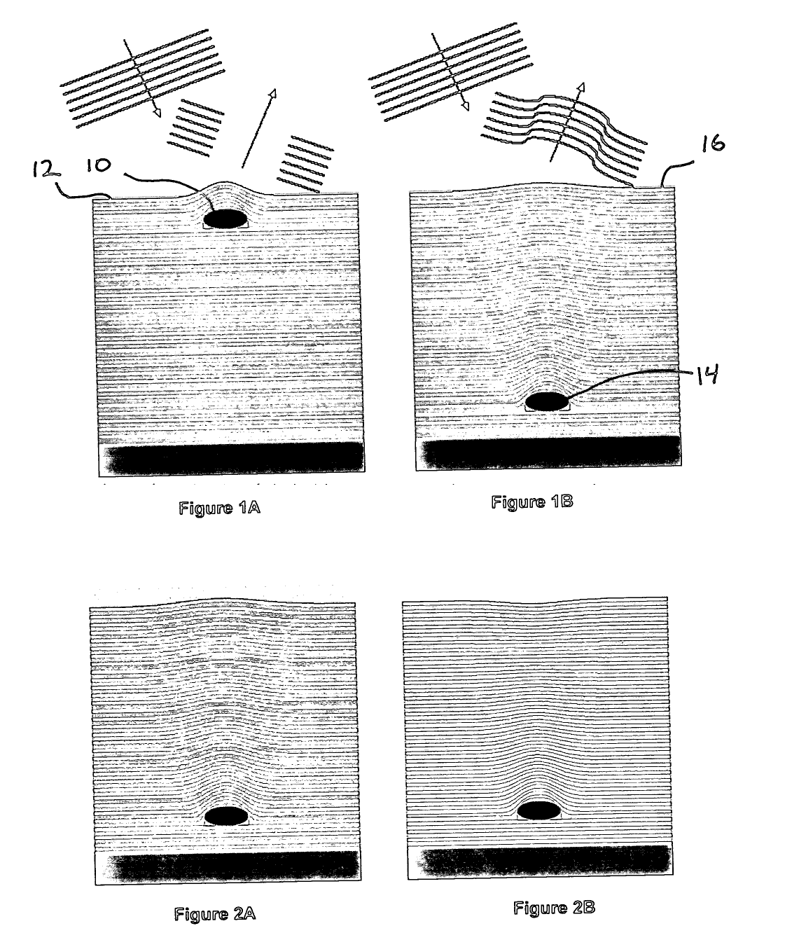

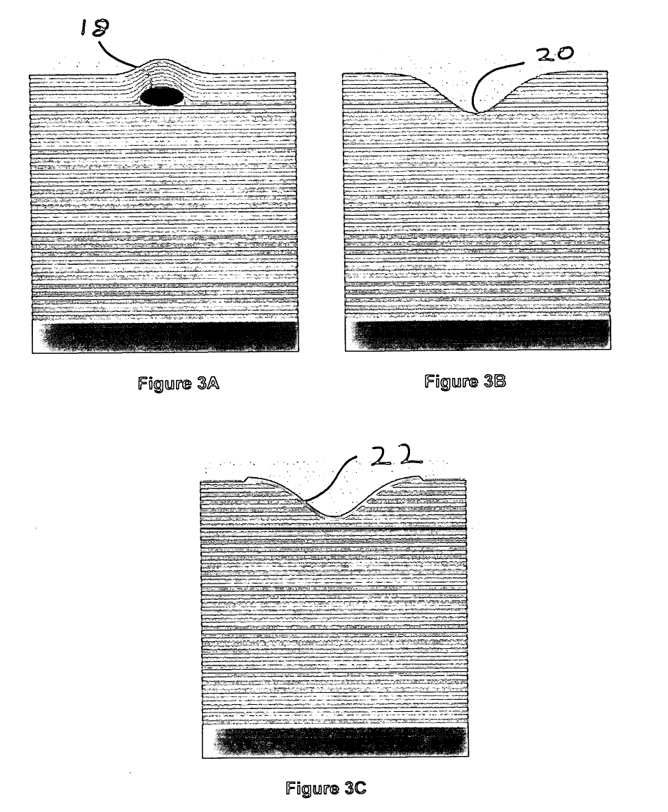

### DETAILED DESCRIPTION OF THE INVENTION

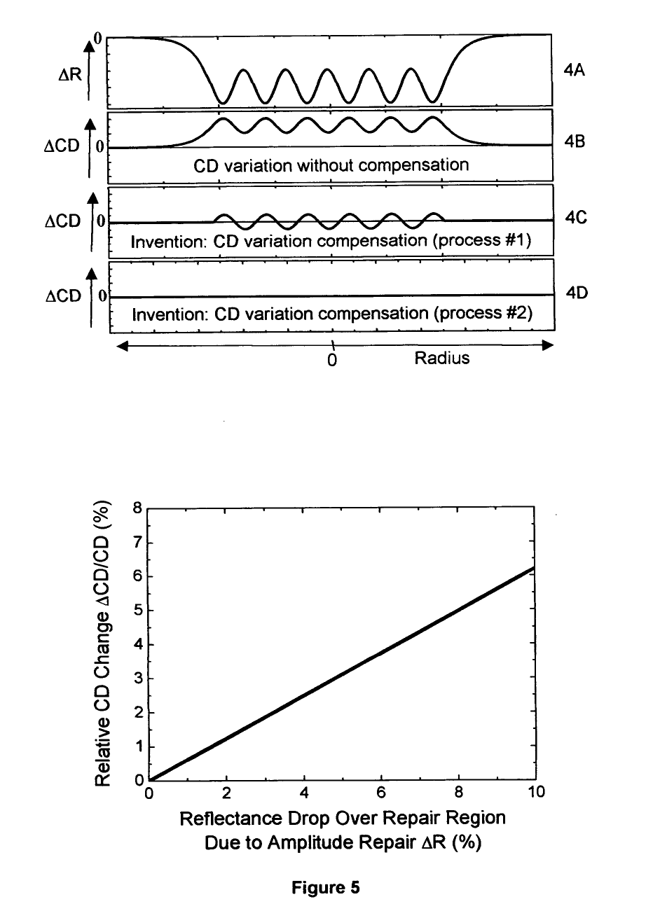

It has been observed that the reflectance varies across the amplitude-defect repair zone (see “Defect Repair For Extreme Ultraviolet Lithography (EUVL) Mask Blanks,” S. P. Hau-Riege et al., Proc. SPIE 5037, (2003), incorporated herein by reference). A typical lineout of the reflectance for a circular repair zone is shown in FIG. 4A. The reflectance often shows a general drop that is primarily due to the capping layer. In addition, the reflectance oscillates due to the varying thickness of the top-most Mo or Si layer. The reflectance variation leads to a change in CD, as schematically shown in FIG. 4B. The dependence of CD on reflectance can be calculated by aerial image calculations, and is shown in FIG. 5 for 35 nm-wide lines.

Phase defect repair successfully reduces the phase variation over the repair zone. However, aerial image calculations have shown that the amplitude of the reflected light is somewhat degraded, leading to a minor but noticeable CD variation.

The present invention compensates for the defect-repair-induced residual variation of the optical properties across the repair zone through modification or alteration of a portion of the absorber pattern on the surface of the mask blank in proximity to the repair zone to compensate for the local disturbance of the electro-magnetic field induced by the repair zone.

Due to the different nature of amplitude and phase defect repair, the repair-zone compensation has to be handled differently for both techniques. The repair zone induced by amplitude-defect repair is typically reproducible, and different repair zones only vary by the depth of the crater. Further, the diameter of the repair zone is commonly a few micrometers, and its depth is only a few tens of nanometers. Two alternative processes are herein provided for the amplitude-repair-zone compensation. The first process compensates for the overall drop of the reflectance over the repair zone by narrowing the absorber pattern on the mask. The resulting reduction in CD variation is shown in FIG. 4C. The second process modifies the absorber pattern for the detailed reflectance variation across the repair zone, accounting for the overall drop and the oscillations. The outcome is a full compensation for the effect of the repair zone, as shown in FIG. 4D. Regardless of which of the two processes are used, the compensation of the amplitude repair zone can be simplified by performing the repair on a grid. The grid points have to be close enough so that defects anywhere on the mask can be repaired if the amplitude defect repair is only applied at the grid points. The advantage of this gridding is that during repair, only the grid point number and crater depth need to be tracked. With this minimal information, the absorber pattern can be modified since the amplitude repair zone is reproducible.

The repair zone induced by phase-defect repair typically varies from defect to defect since the defect-induced multilayer distortion depends on defect size and shape, and the repair parameters have to be chosen accordingly. To compensate for the phase-defect-repair zone, the repair zone needs to be analyzed in detail either through simulations or measurements, and with techniques as described in U.S. Pat. No. 6,235,434, titled “Method for mask repair using defect compensation,” incorporated herein by reference, can be used to compensate for the repair zone.

There are several methods to modify the absorber layer to compensate for the repair zones. One method is to correct the absorber post-patterning using a focused ion beam that allows the removal and deposition of absorber material. Another method is to correct the absorber pattern layout prior to absorber patterning.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

We claim:

1. A method for compensating for defect-repair-induced residual variation of optical properties across a mask blank repair zone, the method comprising altering a portion of an absorber pattern on a surface of said mask blank in proximity to said repair zone to compensate for a local disturbance of an electro-magnetic field induced by said repair zone.

2. The method of claim 1, wherein said repair zone comprises a amplitude repair zone.

3. The method of claim 2, wherein the step of altering a portion of an absorber pattern comprises compensating for an overall drop of reflectance over said repair zone by narrowing said absorber pattern on said mask.

4. The method of claim 2, wherein the step of altering a portion of an absorber pattern comprises modifying said absorber pattern for a detailed reflectance variation across said repair zone.

5. The method of claim 2, wherein the step of altering a portion of an absorber pattern is performed on a grid.

6. The method of claim 5, wherein said grid comprises grid points that are close enough together so that a defect anywhere on said mask can be repaired if the amplitude defect repair is only applied at one or more of said grid points.

7. The method of claim 6, wherein only the grid point number and crater depth need to be tracked.

8. The method of claim 1, wherein said repair zone comprises a phase-defect-repair zone.

9. The method of claim 8, wherein said repair zone is analyzed in detail either through simulations or measurements.

10. The method of claim 9, wherein the step of altering a portion of an absorber pattern comprises correcting the absorber post-patterning using a focused ion beam that allows the removal and deposition of absorber material.

11. The method of claim 8, wherein the step of altering a portion of an absorber pattern comprises correcting the absorber pattern layout prior to absorber patterning.

12. A method, comprising:
locating a defect in a mask blank;
performing a defect repair technique on said mask blank, wherein said technique produces a residual effect comprising a defect-repair-induced residual variation of an optical property across a repair zone;
identifying said defect-repair-induced residual variation; and
compensating for said defect-repair-induced residual variation.

13. The method of claim 12, wherein said defect-repair-induced residual variation comprises a local disturbance of an electro-magnetic field induced by said repair zone, wherein the step of compensating for said defect-repair-induced residual variation comprises altering a portion of an absorber pattern on the surface of said mask blank in proximity to said repair zone to compensate for said local disturbance.

14. The method of claim 13, wherein said repair zone comprises a amplitude repair zone.

15. The method of claim 14, wherein the step of altering a portion of an absorber pattern comprises compensating for an overall drop of reflectance over said repair zone by narrowing said absorber pattern on said mask.

16. The method of claim 14, wherein the step of altering a portion of an absorber pattern comprises modifying said absorber pattern for a detailed reflectance variation across said repair zone.

17. The method of claim 14, wherein the step of altering a portion of an absorber pattern is performed on a grid.

18. The method of claim 17, wherein said grid comprises grid points that are close enough together so that a defect anywhere on said mask can be repaired if the amplitude defect repair is only applied at one or more of said grid points.

19. The method of claim 18, wherein only the grid point number and crater depth need to be tracked.

20. The method of claim 13, wherein said repair zone comprises a phase-defect-repair zone.

21. The method of claim 20, wherein said repair zone is analyzed in detail either through simulations or measurements.

22. The method of claim 21, wherein the step of altering a portion of an absorber pattern comprises correcting the absorber post-patterning using a focused ion beam that allows the removal and deposition of absorber material.

23. The method of claim 20, wherein the step of altering a portion of an absorber pattern comprises correcting the absorber pattern layout prior to absorber patterning.

24. A method comprising compensating for a reflectance variation in mask blank, wherein said reflectance variation is a residual effect from performing a defect repair technique on said mask blank, wherein the step of compensating for a reflectance variation comprises altering a portion of an absorber pattern on the surface of said mask blank.

25. The method of claim 24, wherein said repair zone comprises a amplitude repair zone.

26. The method of claim 25, wherein the step of altering a portion of an absorber pattern comprises compensating for an overall drop of reflectance over said repair zone by narrowing said absorber pattern on said mask.

27. The method of claim 25, wherein the step of altering a portion of an absorber pattern comprises modifying said absorber pattern for a detailed reflectance variation across said repair zone.

28. The method of claim 25, wherein the step of altering a portion of an absorber pattern is performed on a grid.

29. The method of claim 28, wherein said grid comprises grid points that are close enough together so that a defect anywhere on said mask can be repaired if the amplitude defect repair is only applied at one or more of said grid points.

30. The method of claim 29, wherein only the grid point number and crater depth need to be tracked.

31. The method of claim 24, wherein said repair zone comprises a phase-defect-repair zone.

32. The method of claim 31, wherein said repair zone is analyzed in detail either through simulations or measurements.

33. The method of claim 32, wherein the step of altering a portion of an absorber pattern comprises correcting the absorber post-patterning using a focused ion beam that allows the removal and deposition of absorber material.

34. The method of claim 31, wherein the step of altering a portion of an absorber pattern comprises correcting the absorber pattern layout prior to absorber patterning.
